(19) United States
(12) Patent Application Publication
(10) Pub. No.: US 2024/0008229 A1
(43) Pub. Date: Jan. 4, 2024

(54) CARBON NANOTUBES AS THERMAL INTERFACE MATERIAL

(71) Applicant: NTHERMA CORPORATION, Fremont, CA (US)

(72) Inventors: Cattien V. Nguyen, Milpitas, CA (US); Be Van Vo, Santa Clara, CA (US); Anthony Vu, San Jose, CA (US)

(73) Assignee: NTHERMA CORPORATION, Fremont, CA (US)

(21) Appl. No.: 18/369,275

(22) Filed: Sep. 18, 2023

Related U.S. Application Data
(63) Continuation of application No. 14/881,158, filed on Oct. 13, 2015, now abandoned.
(60) Provisional application No. 62/063,253, filed on Oct. 13, 2014.

(51) Int. Cl. H05K 7/20

(52) U.S. Cl. CPC H05K 7/20509; H05K 7/20481

(57) ABSTRACT

Provided herein are carbon nanotubes disposed on a metal substrate containing one or more cavities, methods of making thereof and uses thereof. In some embodiments, an apparatus is provided which includes carbon nanotubes carbon nanotubes disposed on a metal substrate containing one or more cavities.

This application is a continuation of U.S. application Ser. No. 14/881,158, filed Oct. 13, 2015, which claims priority under 35 U.S.C. § 119 (e) from U.S. Provisional Application Ser. No. 62/063,286 filed Oct. 13, 2014, respectively, which are hereby incorporated by reference in their entirety.

### TECHNICAL FIELD

Provided herein are carbon nanotubes disposed on a metal substrate containing one or more cavities, methods of making thereof and uses thereof. In some embodiments, an apparatus is provided which includes carbon nanotubes carbon nanotubes disposed on a metal substrate containing one or more cavities.

### BACKGROUND

Thermal interface materials may be used for example, in microelectronic devices, light emitting diode (LED) devices, power electronics and batteries. The complexity of modern devices requires multiple-levels of integration and heat dissipation is an increasingly critical issue as integrated circuits reach increasingly infinitesimal size. Heat sinks, which function as heat spreaders, are use to transfer heat from the functional devices to the periphery of the packaging area. The poor heat conductivity of air requires thermal interface materials in conductive contact with functional devices and a heat sink, to efficiently transfer heat to the heat sink from the functional devices.

Although, inherent thermal conductivity is of critical importance other parameters need to be optimized in design of a thermal interface material. A thermal interface material should be mechanically flexible to maximize the contact area between the functional devices and the thermal interface material and the thermal interface material and the heat sink. Ideally, the thermal interface material conforms to the surface morphology of both the functional devices and heat sink.

Mechanical strength and resistance to physical cracking during temperature cycling are also advantageous properties of a thermal interface material. Thermal interface materials of low thermal expansion coefficient are highly desirable to avoid significant physical deformation during temperature cycling. Excessive physical deformation of the thermal interface material can cause damage to the functional devices in combination. Finally, thermal stability at the temperature regime of the functional devices is essential to avoid thermal-chemical degradation of the material and properties of the thermal interface material.

Accordingly, what is needed are novel thermal interface materials with superior mechanical strength which are resistant to physical cracking, low thermal expansion coefficient and thermal stability at the operating temperature of the functional device(s).

### SUMMARY

The present invention satisfies these and other need by providing, in one aspect, a substance including carbon nanotubes disposed on at least one side of a metal substrate including one or more cavities.

In another aspect, a method of fabricating a substance including carbon nanotubes disposed on at least one side of a metal substrate including one or more cavities is provided. The method includes polishing the metal substrate to a root mean square roughness of less than about 100 μm, depositing catalyst on the metal substrate, forming one or more cavities on the metal substrate and depositing carbon nanotubes on the catalyst disposed on the metal substrate.

In still another aspect, another method of fabricating a substance including carbon nanotubes disposed on at least one side of a metal substrate including one or more cavities is provided. The method includes polishing the metal substrate to a root mean square roughness of less than about 100 μm, forming one or more cavities on the metal substrate, depositing catalyst on the metal substrate and depositing carbon nanotubes on the catalyst disposed on the metal substrate.

In still another aspect, another method of fabricating a substance including carbon nanotubes disposed on at least one side of a metal substrate including one or more cavities is provided. The method includes polishing the metal substrate, which includes a catalyst or is a catalyst to a root mean square roughness of less than about 100 μM, forming one or more cavities on the metal substrate and depositing carbon nanotubes on the metal substrate.

In still another aspect, an apparatus is provided, which includes a device, a heat sink and a thermal interface material. The thermal interface material, which includes carbon nanotubes disposed on at least one side of a metal substrate with one or more cavities is disposed between the device and the heat sink where the thermal interface material is in conductive contact with the device and the heat sink.

### BRIEF DESCRIPTION OF THE DRAWINGS

FIG. 1 illustrates an exemplary flowchart for fabricating carbon nanotubes on a metal substrate including one or more cavities, where the cavities are introduced in the metal substrate prior to catalyst deposition.

FIG. 2 illustrates an exemplary flowchart for fabricating carbon nanotubes on a metal substrate including one or more cavities, where the cavities are introduced in the metal substrate after catalyst deposition.

FIG. 3 illustrates an exemplary flowchart for fabricating carbon nanotubes on a metal substrate including one or more cavities, where catalyst deposition is not required.

FIG. 4 illustrates a metal substrate with a thickness t.

FIG. 5 illustrates a metal substrate with one or more cavities with a diameter d and a cavity-to-cavity separation D.

FIG. 6 illustrates deposition of carbon nanotubes on a metal substrate with one or more cavities, where the carbon nanotubes are vertically aligned with respect to the metal substrate surface and are deposited on the portion of the metal substrate without cavities.

FIG. 7 illustrates a cross-section of vertically aligned carbon nanotubes deposited on both sides of a metal substrate including one or more cavities, where the carbon nanotubes have lower density in areas around the cavity edges.

FIG. 8 illustrates an embodiment of an apparatus which includes a device, a heat sink and a thermal interface material. In the depicted embodiment, the thermal interface material, includes vertically aligned carbon nanotubes disposed on both side of a metal substrate including cavities. The thermal interface material is in conductive contact with the device and the heat sink and dissipates heat from the device to the heat sink.

FIG. 9 illustrates another embodiment of an apparatus which includes a device, a heat sink and a thermal interface material. The thermal interface material, includes vertically aligned carbon nanotubes disposed on both side of a metal substrate including cavities. The carbon nanotube density is lower at the edges of the cavities. The thermal interface material is in conductive contact with the device and the heat sink and dissipates heat from the device to the heat sink.

### DETAILED DESCRIPTION

### Definitions

Unless defined otherwise, all technical and scientific terms used herein have the same meaning as is commonly understood by one of ordinary skill in the art to which this invention belongs. In the event that there is a plurality of definitions for a term herein, those in this section prevail unless stated otherwise.

As used herein “carbon nanotubes” refer to allotropes of carbon with a cylindrical structure. Carbon nanotubes may have defects such as inclusion of C5 and/or C7 ring structures, such that the carbon nanotube is not straight; and may have contain coiled structures; and may contain randomly distributed defected sites in the C—C bonding arrangement. Carbon nanotubes may contain one or more concentric cylindrical layers.

As used herein “catalysts” or “metal catalysts” refer to a metal or a combination of metals such as Fe, Ni, Co, Cu, Au, etc. that are used in the breakdown of hydrocarbon gases and aid in the formation of carbon nanotubes by chemical vapor deposition process.

As used herein “chemical vapor deposition” refers to plasma-enhanced chemical vapor deposition or thermal chemical vapor deposition.

As used herein “plasma-enhanced chemical vapor deposition” refers to the use of plasma (e.g., glow discharge) to transform a hydrocarbon gas mixture into excited species which deposit carbon nanotubes on a surface.

As used herein “thermal chemical vapor deposition” refers to the thermal decomposition of hydrocarbon vapor in the presence of a catalyst which may be used to deposit carbon nanotubes on a surface.

As used herein “physical vapor deposition” refers to vacuum deposition methods used to deposit thin films by condensation of a vaporized of desired film material onto film materials and includes techniques such as cathodic arc deposition, electron beam deposition, evaporative deposition, pulsed laser deposition and sputter deposition.

As used herein “thermal interface material” refers to a material that conducts heat from functional device(s) to a heat sink.

As used herein “functional device(s)” refers to any device(s) which generate heat in the course of operation. Examples of functional devices include microelectronics computer processing units, microelectronics memory devices, light emitting diodes, a battery, a battery systems, power supplies, etc.

As used herein “heat sink” refers to a block of metal, with elevated surface area, which may be generated by complex structure, which can spread heat and dissipate heat by convection.

Carbon nanotubes are a relatively new material with exceptional physical properties, such as superior current carrying capacity, high thermal conductivity, good mechanical strength, and large surface area, which are advantageous in a number of applications. Carbon nanotubes possess exceptional thermal conductivity with a value as high as 3000 W/mK which is only lower than the thermal conductivity of diamond. Carbon nanotubes are mechanically strong and thermally stable above 400° C. under atmospheric conditions. Carbon nanotubes have reversible mechanical flexibility particularly when vertically aligned. Accordingly, carbon nanotubes are able to mechanically conform to different surface morphologies because of this intrinsic flexibility. Additionally, carbon nanotubes have a low thermal expansion coefficient and retain flexibility in confined conditions under elevated temperatures.

Economically providing carbon nanotubes, in a controlled manner with practical integration and/or packaging are essential to implementing many potential carbon nanotube technologies. A compelling application of carbon nanotubes is incorporation into thermal interface materials.

In one aspect, provided herein, is a substance which includes carbon nanotubes disposed on at least one side of a metal substrate incorporating one or more cavities. In some embodiments, the one or more cavities are an aperture which breaches the substance. In some embodiments, the one or more cavities are a random shape. In other embodiments, the one or more cavities are a circle, triangle, square, pentagon, hexagon, heptagon, octagon or combinations thereof.

In some embodiments, the one or more cavities are randomly dispersed on the metal substrate. In some embodiments, the one or more cavities are regularly dispersed on the metal substrate. In still other embodiments, the one or more cavities comprise a patterned array on the metal substrate.

In some embodiments, the one or more cavities have an approximate width of between about 10 μm and about 10 cm. In other embodiments, the one or more cavities have an approximate width of between about 1 cm and about 10 cm. In still other embodiments, the one or more cavities have an approximate width of between about 1 mm and about 10 cm. In still other embodiments, the one or more cavities have an approximate width of between about 100 μm and about 10 cm. In still other embodiments, the one or more cavities have an approximate width of between about 10 μm and about 100 μm. In still other embodiments, the one or more cavities have an approximate width of between about 10 μm and about 1 mm. In still other embodiments, the one or more cavities have an approximate width of between about 10 μm and about 1 cm.

In some embodiments, the cavities in the array are separated by an approximate width of between about 10 μm and about 10 cm. In other embodiments, the cavities in the array are separated by an approximate width of between about 1 cm and about 10 cm. In still other embodiments, the cavities in the array are separated by an approximate width of between about 1 mm and about 10 cm. In still other embodiments, the cavities in the array are separated by an approximate width of between about 100 μm and about 10 cm. In still other embodiments, the cavities in the array are separated by an approximate width of between about 10 μm and about 100 μm. In still other embodiments, the cavities in the array are separated by an approximate width of between about 10 μm and about 1 mm. In still other embodiments, the cavities in the array are separated by an approximate width of between about 10 μm and about 1 cm.

It should be noted that all possible combinations of cavity separations and cavity widths with are operationally feasible are envisaged in the present invention.

In some embodiments, the carbon nanotubes are randomly aligned. In other embodiments, the carbon nanotubes are vertically aligned. In still other embodiments, the aerial density of the carbon nanotubes between about 2 mg/cm² and about 1 mg/cm². In still other embodiments, the density of the carbon nanotubes between about 2 mg/cm² and about 0.2 mg/cm².

In some embodiments, the density of carbon nanotubes disposed at the cavity edges is lower than the bulk density of the carbon nanotubes disposed on the metal surface. In other embodiments, the density of carbon nanotubes disposed at the cavity edges is less than about 95% of the bulk density of the carbon nanotubes disposed on the metal surface. In other embodiments, the density of carbon nanotubes disposed at the cavity edges is less than about 90% of the bulk density of the carbon nanotubes disposed on the metal surface. In other embodiments, the density of carbon nanotubes disposed at the cavity edges is less than about 95% of the bulk density of the carbon nanotubes disposed on the metal surface. In other embodiments, the density of carbon nanotubes disposed at the cavity edges is less than about 70% of the bulk density of the carbon nanotubes disposed on the metal surface. In other embodiments, the density of carbon nanotubes disposed at the cavity edges is less than about 95% of the bulk density of the carbon nanotubes disposed on the metal surface. In other embodiments, the density of carbon nanotubes disposed at the cavity edges is less than about 50% of the bulk density of the carbon nanotubes disposed on the metal surface. In other embodiments, the density of carbon nanotubes disposed at the cavity edges is less than about 95% of the bulk density of the carbon nanotubes disposed on the metal surface. In other embodiments, the density of carbon nanotubes disposed at the cavity edges is less than about 10% of the bulk density of the carbon nanotubes disposed on the metal surface.

In some embodiments, the density of carbon nanotubes disposed at the cavity edges is less than about 95% of the bulk density of the carbon nanotubes disposed on the metal surface. In other embodiments, the density of carbon nanotubes disposed at the cavity edges is less than about 90% of the bulk density of the carbon nanotubes disposed on the metal surface.

In some embodiments, vertically aligned carbon nanotubes have a thermal conductivity of greater than about 50 W/mK. In other embodiments, vertically aligned carbon nanotubes have a thermal conductivity of greater than about 70 W/mK.

In some embodiments, vertically aligned carbon nanotubes comprising a patterned array have a thermal conductivity of greater than about 50 W/mK. In other embodiments, vertically aligned carbon nanotubes comprising a patterned array have a thermal conductivity of greater than about 70 W/mK. In still other embodiments, vertically aligned carbon nanotubes comprising a patterned array have a thermal conductivity of greater than about 100 W/mK.

In some embodiments, the thickness of the vertically aligned carbon nanotubes is between than about 100 μm and about 500 μm. In other embodiments, the thickness of the vertically aligned carbon nanotubes is less than about 100 μm.

In some embodiments, carbon nanotubes are disposed on two opposing sides of the metal substrate. In other embodiments, carbon nanotubes are disposed on two sides of the metal substrate. In still other embodiments, carbon nanotubes are disposed on three sides of the metal substrate. In still other embodiments, carbon nanotubes are disposed on all sides of the metal substrate.

In some embodiments, the thickness of the metal substrate is between about 0.05 μM and about 100 cm. In other embodiments, the thickness of the metal substrate is between about 0.05 mm and about 5 mm. In still other embodiments, the thickness of the metal substrate is between about 0.1 mm and about 2.5 mm. In still other embodiments, the thickness of the metal substrate is between about 0.5 mm and about 1.5 mm. In still other embodiments, the thickness of the metal substrate is between about 1 mm and about 5 mm. In still other embodiments, the thickness of the metal substrate is between about 0.05 mm and about 1 mm. In still other embodiments, the thickness of the metal substrate is between about 0.05 mm and about 0.5 mm. In still other embodiments, the thickness of the metal substrate is between about 0.5 mm and about 1 mm. In still other embodiments, the thickness of the metal substrate is between about 1 mm and about 2.5 mm. In still other embodiments, the thickness of the metal substrate is between about 2.5 mm and about 5 mm. In still other embodiments, the thickness of the metal substrate is between about 100 μM and about 5 mm. In still other embodiments, the thickness of the metal substrate is between about 10 μM and about 5 mm.

In still other embodiments, the thickness of the metal substrate is greater than 100 μM. In still other embodiments, the thickness of the metal substrate is less than 100 μM.

In some embodiments, the metal substrate includes iron, nickel, aluminum, cobalt, copper, chromium, gold and combinations thereof. In other embodiments, the metal substrate includes iron, nickel, cobalt, copper, gold or combinations thereof.

In some embodiments, the metal substrate is an alloy of two or more of iron, nickel, cobalt, copper, chromium, aluminum, gold and combinations thereof. In other embodiments, the metal substrate is an alloy of two or more of iron, nickel, cobalt, copper, gold and combinations thereof.

In some embodiments, the metal substrate is high temperature metal alloy. In other embodiments, the metal substrate is stainless steel. In still other embodiments, the metal substrate is a high temperature metal alloy on which a catalyst film is deposited for growing carbon nanotubes. In still other embodiments, the metal substrate is stainless steel on which a catalyst film is deposited for growing carbon nanotubes.

In some embodiments, the metal substrate is a metal or combination of metals which are thermally stable at greater than 500° C. In other embodiments, the metal substrate is a metal or combination of metals which are thermally stable at greater than 600° C. In still other embodiments, the metal substrate is a metal or combination of metals which are thermally stable at greater than 700° C. In some of the above embodiments, the combination of metals is stainless steel.

In some embodiments, the metal substrate has a thickness of less than about 100 μM and a surface root mean square roughness of less than about 250 nm. In some embodiments, the metal substrate has a thickness of greater than about 100 μM and a surface root mean square roughness of less than about 250 nm. In still other embodiments, the metal substrate has a thickness of less than about 100 μM and a surface root mean square roughness of less than about 250 nm and includes iron, nickel, cobalt, copper, gold or combinations thereof. In still other embodiments, the metal substrate has a thickness of greater than about 100 μM and a surface root mean square roughness of less than about 250 nm and includes iron, nickel, cobalt, copper, gold or combinations thereof. In still other embodiments, the metal substrate has a thickness of less than about 100 μM and a surface root mean square roughness of less than about 250 nm and includes a catalyst film. In still other embodiments, the metal substrate has a thickness of greater than about 100 μM and a surface root mean square roughness of less than about 250 nm and includes a catalyst film. In some of the above embodiments, the root mean square roughness is less than about 100 nm.

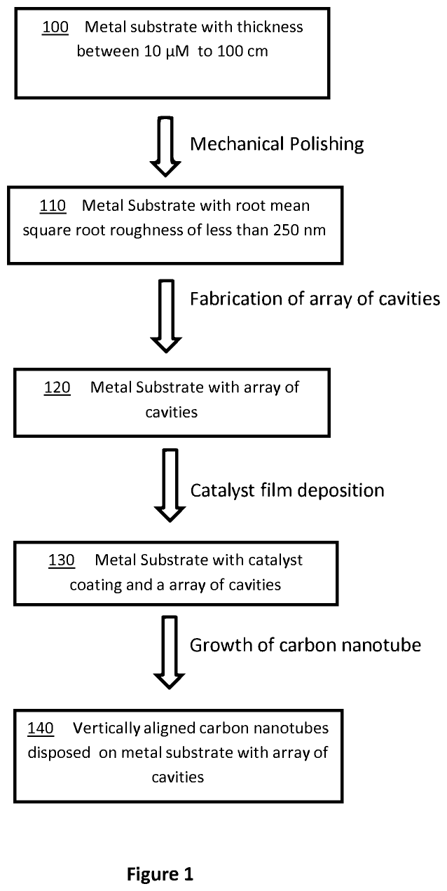

Referring now to FIG. 1, one embodiment of a method of fabricating a substance including carbon nanotubes disposed on at least one side of a metal substrate incorporating one or more cavities is illustrated. A metal substrate with a thickness between 10 μm and 100 cm is provided at 100. Mechanical polishing, which can be accomplished by a variety of methods know to the skilled artisan then provides a metal substrate with a root mean square roughness of less than about 250 nm at 110 which is used to prepare a metal substrate including an array of cavities at 120. Then, deposition of a catalyst film yields a metal substrate with a catalyst coating which includes an array of cavities at 130. Finally, carbon nanotubes are grown on the metal substrate to provide vertically aligned carbon nanotubes disposed on a metal substrate with an array of cavities at 140.

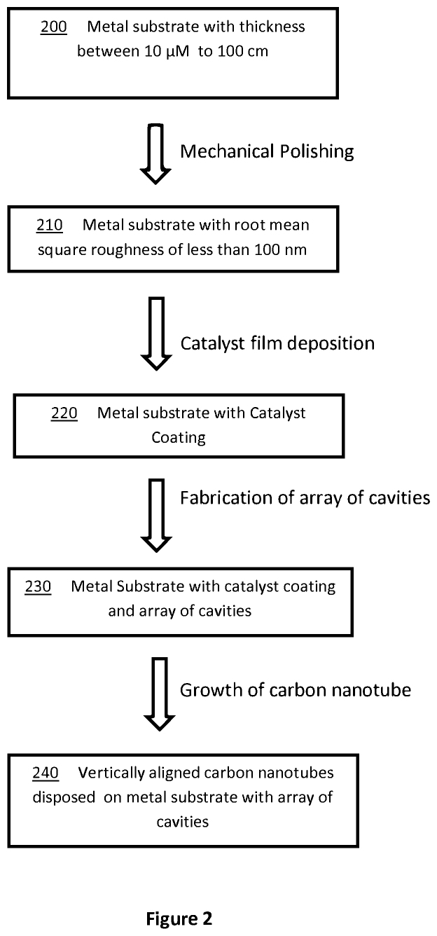

Referring now to FIG. 2, another embodiment of a method of fabricating a substance including carbon nanotubes disposed on at least one side of a metal substrate incorporating one or more cavities is illustrated. A metal substrate with a thickness between 10 μm and 100 cm is provided at 200. Mechanical polishing, which can be accomplished by a variety of methods know to the skilled artisan then provides a metal substrate with a root mean square roughness of less than about 250 nm at 210. Then deposition of a catalyst film yields a metal substrate with a catalyst coating at 220 which is used to fabricate an array of cavities at 230. Finally, carbon nanotubes are grown on the metal substrate to provide vertically aligned carbon nanotubes disposed on a metal substrate with an array of cavities at 240.

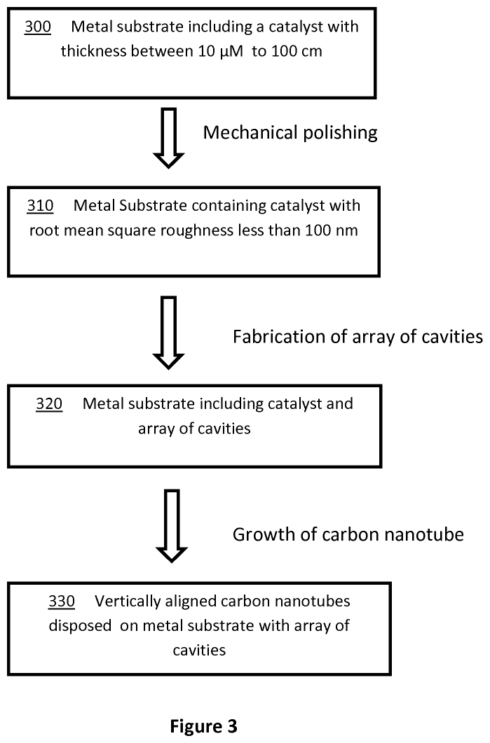

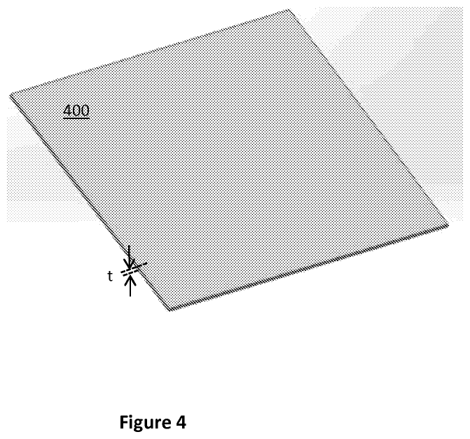

Referring now to FIG. 3, another embodiment of a method of fabricating a substance including carbon nanotubes disposed on at least one side of a metal substrate incorporating one or more cavities is illustrated. A metal substrate including a catalyst with a thickness between 10 μm and 100 cm is provided at 300. Mechanical polishing, which can be accomplished by a variety of methods know to the skilled artisan then provides a metal substrate with a root mean square roughness of less than about 250 nm at 310 which is used to fabricate an array of cavities at 320. Finally, carbon nanotubes are grown on the metal substrate to provide vertically aligned carbon nanotubes disposed on a metal substrate with an array of cavities at 330.

In some of the above embodiments, the catalyst forms a layer on the metal substrate.

In some of the above embodiments, solution deposition techniques are used to deposit the catalyst. In other embodiments, solution deposition techniques include solution dipping, spraying, ink jet and print screening.

In some of the above embodiments, physical deposition techniques are used to deposit the catalyst. In other embodiments, physical deposition techniques include ion beam sputtering, electron beam deposition, evaporative metal heating and pulsed laser deposition.

Referring now to FIG. 4, one embodiment of a metal substrate 400 with a thickness t is illustrated. The metal substrate can include any of the metals described above and can be any thickness described above.

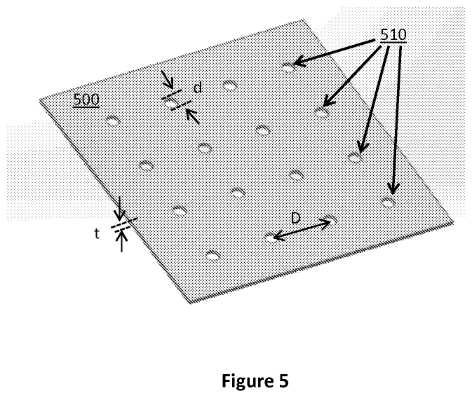

FIG. 5 illustrates one embodiment of a metal substrate 500 which includes patterned array of cavities 510. In some embodiments, the metal substrate 500 includes a 2×2 array of cavities 510. In other embodiments, the metal substrate 500 includes a array of cavities 510 greater than 2×2. In some embodiments, the cavities 510 are in a regular pattern. In other embodiments, the cavities 510 are in a random pattern. The cavities can have any geometry or combination of geometries previously described above. In some embodiments, the width of cavities d has any of the dimensions previously described above. In some embodiments, the N×N array of cavities 510 has a separation D with any of the distances described above.

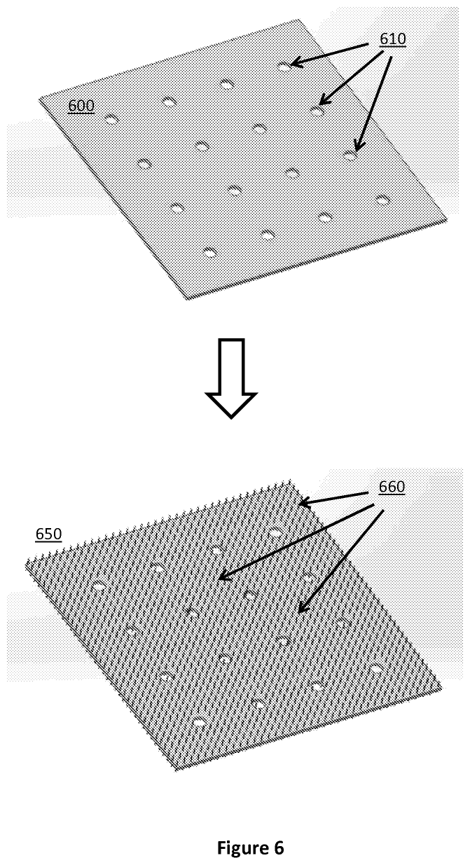

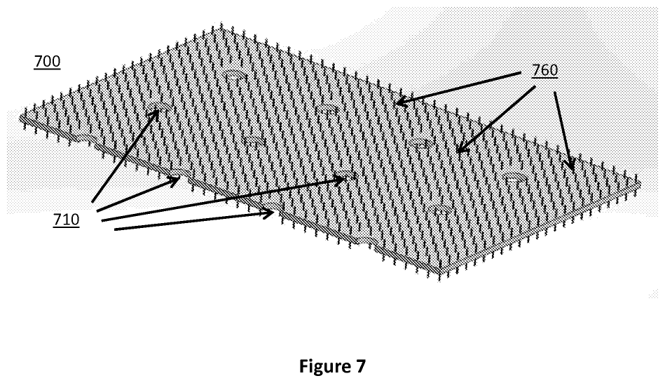

FIG. 6 illustrates one embodiment of carbon nanotube 660 deposition on a metal substrate 600 with cavities 610. The carbon nanotubes 660 are vertically aligned with respect to the metal substrate surface 650 and are deposited on the metal substrate 650 without cavities 610.

FIG. 7 illustrates one embodiment of vertically aligned carbon nanotubes 760 deposited on both sides of metal substrate 700 which includes cavities 710, where the carbon nanotubes have lower density in areas around the edges of cavity 710.

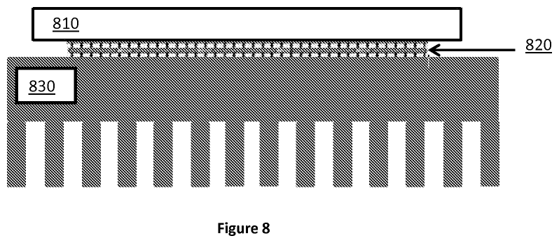

FIG. 8 illustrates one embodiment of an apparatus which includes a device 810, a heat sink 830 and a thermal interface material 820. The thermal interface material 820, includes vertically aligned carbon nanotubes disposed on both side of a metal substrate which includes cavities. The thermal interface material 820 is in conductive contact with device 810 and heat sink 830 and conducts heat from device 810 to heat sink 830.

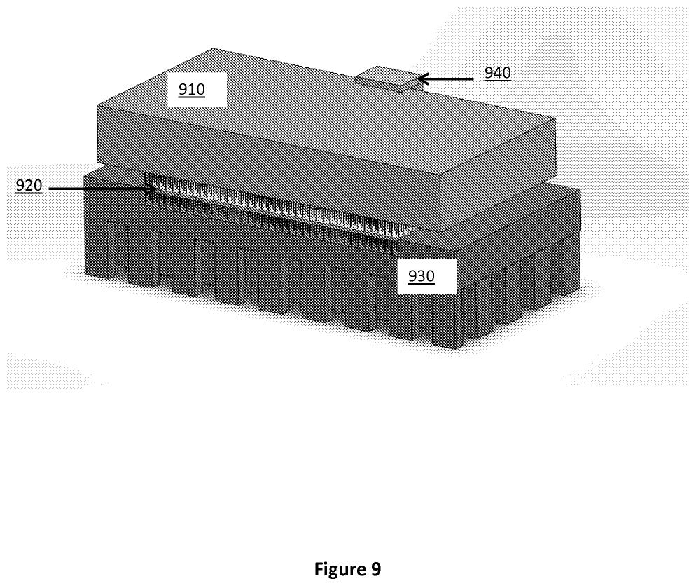

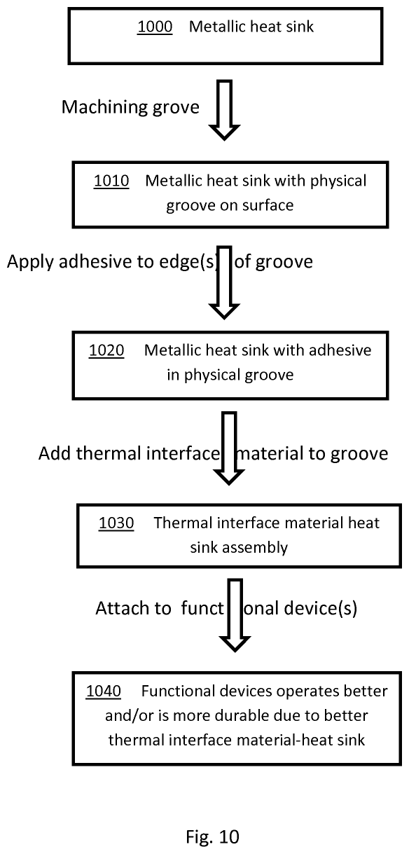

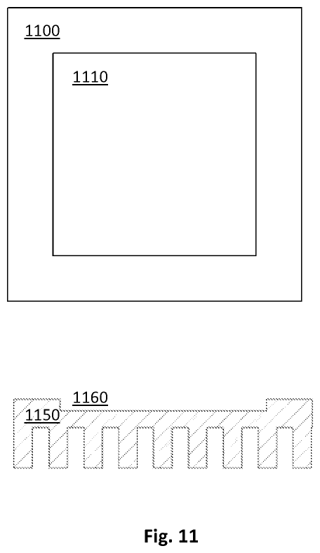

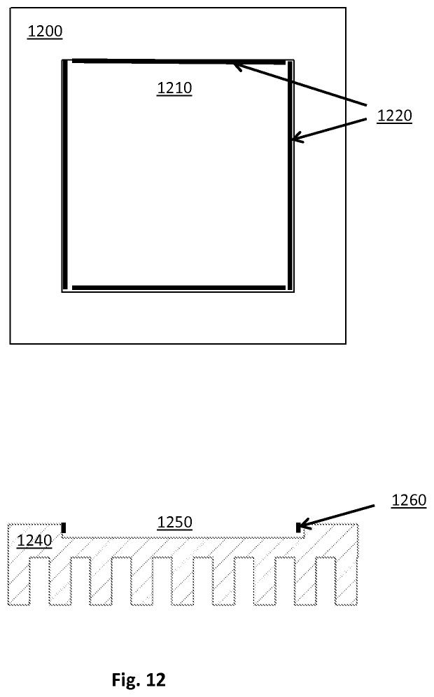

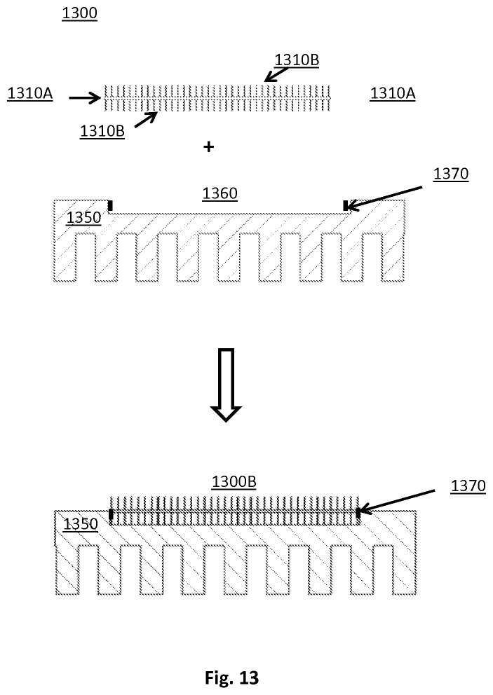

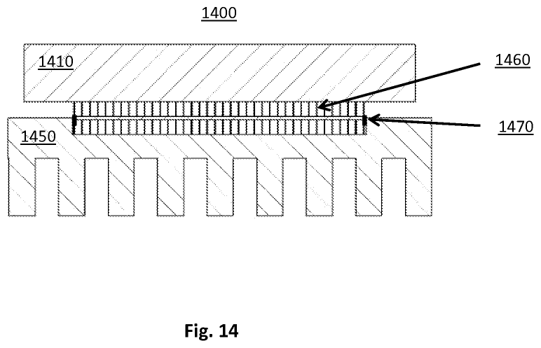

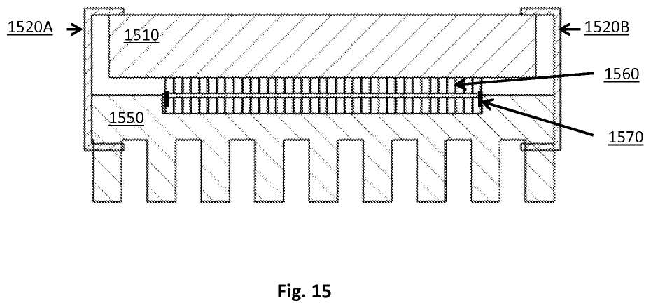

FIG. 9 illustrates another embodiment of an apparatus which includes a device 910, a heat sink 930 a thermal interface material 920 and a clamp 940 which secures. The thermal interface material 920 includes vertically aligned carbon nanotubes disposed on both side of a metal substrate which includes cavities. The carbon nanotube density is lower at the edges of the cavities. The thermal interface material 920 is in conductive contact with device 910 and heat sink 930 and conducts heat from device 910 to heat sink 930.

In some of the above embodiments, the device is a light emitting diode, a microelectronic chip, a power chip, a battery or a battery pack.

Finally, it should be noted that there are alternative ways of implementing the present invention. Accordingly, the present embodiments are to be considered as illustrative and not restrictive, and the invention is not to be limited to the details given herein, but may be modified within the scope and equivalents of the appended claims.

All publications and patents cited herein are incorporated by reference in their entirety.

What is claimed is:

1. An apparatus comprising:
a metal substrate comprising carbon nanotubes directly attached to the two opposing metal surfaces of the metal substrate, which includes one or more apertures breaching the metal surfaces of the metal substrate, wherein both metal surfaces of the metal substrate have root mean square roughness features of less than about 250 μm, include catalyst and are comprised of iron, nickel, cobalt or combinations thereof;
a heat sink with a surface depression;
wherein the carbon nanotubes attached to the metal substrate are in conductive contact with the surface depression of the heat sink and the thickness of the metal substrate with the attached carbon nanotubes is greater than the depth of the depression on the heat sink.

2. The apparatus of claim 1, wherein the metal substrate and the heat sink are attached with an adhesive.

3. The apparatus of claim 2, wherein the adhesive is comprised of a thermal paste, thermal grease, epoxy, silver, epoxy or combinations thereof.

4. The apparatus of claim 2, wherein the adhesive is applied to an edge of the depression.

5. The apparatus of claim 1, wherein the heat sink is comprised of aluminum or aluminum alloy.

6. The apparatus of claim 1, wherein the heat sink is comprised of copper or copper alloy.

7. The apparatus of claim 1, wherein the depression has a depth between about 500 μm and about 2000 μm.

8. The apparatus of claim 1, wherein the depression has a depth between about 50 μm and about 500 μm.

9. The apparatus of claim 1, further comprising:
a device in conductive contact with the carbon nanotubes attached to the metal substrate;
wherein the metal substrate is disposed between the heat sink and the device.

10. The apparatus of claim 9, wherein the device is a microelectronic device, a computer, a LED device, a power electronic device, a battery, a battery system, or a space system.

11. A method of making the apparatus of claim 9 comprising:
attaching the metal substrate to the heat sink depression; and
attaching the device to the metal substrate.
